(19) United States
(12) Patent Application Publication
(10) Pub. No.: US 2026/0344353 A1
(43) Pub. Date: Oct. 29, 2026

(54) BONDING APPARATUS AND BONDING METHOD FOR CHIP

(71) Applicant: WUHAN XINXIN SEMICONDUCTOR MANUFACTURING CO., LTD., WUHAN (CN)

(72) Inventors: CHAO TAO, WUHAN (CN); JUNZHOU LONG, WUHAN (CN); LI WANG, WUHAN (CN)

(21) Appl. No.: 19/698,854

(22) Filed: Jun. 5, 2026

Related U.S. Application Data
(63) Continuation of application No. PCT/CN2023/138939, filed on Dec. 14, 2023.

(30) Foreign Application Priority Data
Dec. 7, 2023 (CN) 202311685313.0

(51) Int. Cl. H10P 72/50; G06T 7/00; G06T 7/73; H10P 72/00

(52) U.S. Cl. CPC H10P 72/53; G06T 7/001; G06T 7/74; H10P 72/0446; G06T 2207/30108; G06T 2207/30204

(57) ABSTRACT

A bonding apparatus and a bonding method for a chip. The apparatus includes: a movable pick-up stage, configured to move a first element; a carrier stage, configured to move a second element; a correction component, providing a correction mark; and an image-acquisition device. The image-acquisition device is configured to read an alignment mark of the first element and the correction mark, and determine a first relative positional relationship between the first element and the correction component; and further configured to read an alignment mark of the second element and the correction mark, and determine a second relative positional relationship between the second element and the correction component. The bonding apparatus is configured to determine an alignment offset between the first element and the second element; and perform an alignment compensation operation, enabling the first element and the second element to be aligned and bonded.

### CROSS-REFERENCE TO RELATED APPLICATIONS

The present application is a continuation-application of International (PCT) Patent Application No. PCT/CN2023/138939, filed on Dec. 14, 2023, which claims the priority of the Chinese patent application No. 202311685313.0, filed on Dec. 7, 2023, the entire content of which is incorporated herein by reference.

### TECHNICAL FIELD

The present disclosure relates to the technical field of semiconductor manufacturing, in particular to a bonding apparatus and a bonding method for a chip.

### BACKGROUND

As semiconductor technology enters the post-Moore era, to meet the demands for high integration density and high performance, chip structures are developing in three dimensions. Among them, realizing the fabrication of stacked chips through bonding technology is one of the important technologies for “More than Moore's Law”. Bonding accuracy is a crucial parameter of the bonding process and has a significant impact on the application of the bonding process.

### SUMMARY OF THE DISCLOSURE

According to various embodiments of the present disclosure, a bonding apparatus and a bonding method for a chip are provided.

A bonding apparatus for a chip provided by the present disclosure includes:
a movable pick-up stage, configured to move a first element;
a carrier stage, configured to carry and move a second element;
a correction component, configured to provide a correction mark; wherein the correction component maintains a fixed distance from the first element or the second element; and
an image acquisition device, configured to read an alignment mark of the first element and the correction mark of the correction component, and determine a first relative positional relationship between the first element and the correction component based on the alignment mark of the first element and the correction mark; and further configured to read an alignment mark of the second element and the correction mark of the correction component, and determine a second relative positional relationship between the second element and the correction component based on the alignment mark of the second element and the correction mark;
wherein the bonding apparatus is configured to determine an alignment offset between the first element and the second element based on the first relative positional relationship and the second relative positional relationship; and based on the alignment offset, drive at least one of the movable pick-up stage and the carrier stage to perform adjustments for executing an alignment compensation operation, enabling the first element and the second element to be aligned and bonded.

In another aspect, a bonding method provided by the present disclosure, applied to a bonding apparatus, includes:
acquiring an alignment mark of a first element and a correction mark of a correction component, and determining a first relative positional relationship between the first element and the correction component based on coordinate information of the alignment mark of the first element and coordinate information of the correction mark;
acquiring an alignment mark of a second element and the correction mark of the correction component, and determining a second relative positional relationship between the second element and the correction component based on coordinate information of the alignment mark of the second element and the coordinate information of the correction mark, wherein the correction component maintains a fixed distance with the first element or the second element;
determining an alignment offset between the first element and the second element based on the first relative positional relationship and the second relative positional relationship; and
driving, by the bonding apparatus, at least one of the first element and the second element based on the alignment offset to perform an alignment compensation operation, enabling the first element and the second element to be aligned and bonded.

In another aspect, a bonding method provided by the present disclosure includes:
providing a correction component, wherein the correction component is a transparent, semi-transparent, or perforated alignment plate arranged with an alignment mark;
configuring the correction component to maintain a fixed distance from a first element or a second element;
driving the correction component and the first element to a first position, and simultaneously reading, by an image acquisition device, an alignment mark of the first element at the first position and the alignment mark of the correction component through or via the correction component, to determine a first relative positional relationship between the first element and the correction component;
driving the correction component and the second element to a second position, and simultaneously reading, by the image acquisition device, an alignment mark of the second element at the second position and the alignment mark of the correction component through or via the correction component, to determine a second relative positional relationship between the second element and the correction component;
determining an alignment deviation between the first element and the second element based on the first relative positional relationship and the second relative positional relationship; and
adjusting the first element and/or the second element based on the alignment deviation to align and bond the first element and the second element.

Details of one or more embodiments of the present disclosure are set forth in the accompanying drawings and description below. Other features, objects, and advantages of the present disclosure will be apparent from the description, drawings, and claims.

### BRIEF DESCRIPTION OF THE DRAWINGS

To illustrate the technical solutions in the embodiments of the present disclosure more clearly, the following briefly introduces the accompanying drawings required for describing the embodiments. Obviously, the drawings in the following description are only some embodiments of the present disclosure. For those skilled in the art, other drawings may be obtained based on these drawings without creative effort.

FIG. 1 is a schematic structural diagram of a bonding apparatus according to a first implementation of the present disclosure.

FIG. 2 is a schematic structural diagram of a bonding apparatus according to a first implementation of the present disclosure.

FIG. 3 is a schematic diagram of a first coordinate system of one correction mark corresponding to a bonding apparatus according to some embodiments of the present disclosure.

FIG. 4 is a schematic diagram of a first coordinate system of two correction marks corresponding to a bonding apparatus according to some embodiments of the present disclosure.

FIG. 5 is a schematic diagram of a second coordinate system of one correction mark corresponding to a bonding apparatus according to some embodiments of the present disclosure.

FIG. 6 is a schematic diagram of a coordinate system of two correction marks corresponding to a bonding apparatus according to some embodiments of the present disclosure.

FIG. 7 is a schematic flowchart of a bonding method according to some embodiments of the present disclosure.

FIG. 8 is a schematic diagram of a bonding coordinate system corresponding to a bonding apparatus according to some embodiments of the present disclosure.

FIG. 9 is a schematic diagram of a process of bonding a first element and a second element according to some embodiments of the present disclosure.

FIG. 10 is a schematic diagram of coordinate information of a first element and a second element, that are bonded, in a bonding coordinate system according to some embodiments of the present disclosure.

In the drawings: bonding apparatus 10, movable pick-up stage 100, first drive assembly 110, first driving member 111, second driving member 112, third driving member 113, correction component 200, carrier stage 300, second drive assembly 310, image-acquisition device 400, first image-acquisition device 410, second image-acquisition device 420, machine station 500, base 510, machine frame 520, supply platform 600, first element 20, second element 30.

### DETAILED DESCRIPTION

The technical solutions in the embodiments of the present disclosure will be clearly and completely described below with reference to the accompanying drawings in the embodiments of the present disclosure. Obviously, the described embodiments are only a part of the embodiments of the present disclosure, and not all of them. Based on the embodiments in the present disclosure, all other embodiments obtained by those skilled in the art without creative effort shall fall within the scope of the present disclosure.

The terms “first”, “second”, and “third” in the present disclosure are for descriptive purposes only and are not to be construed as indicating or implying relative importance or implicitly indicating the quantity of the indicated technical features. Thus, features defined as “first”, “second”, and “third” may explicitly or implicitly include at least one of such features. The meaning of “a plurality” in the description of the present disclosure is at least two, such as two, three, etc., unless otherwise specifically and clearly defined. Directional indications (such as up, down, left, right, front, back . . . ) in the embodiments of the present disclosure are only intended to explain the relative positional relationships and movements between various components in a specific posture (as shown in the drawings). When the specific posture changes, the directional indications will also change accordingly. In addition, the terms “include” and “have” and any variations thereof are intended to cover non-exclusive inclusion. For example, a process, method, system, product, or device comprising a series of steps or units is not limited to the listed steps or units, but may in some embodiments also include steps or units not listed, or in some embodiments also include other inherent steps or units of these processes, methods, products, or devices.

Mentioning “embodiments” in this text means that a particular feature, structure, or characteristic described in connection with the embodiment may be included in at least one embodiment of the present disclosure. The appearance of this phrase in various places in the specification does not necessarily all refer to the same embodiment, nor is it an independent or alternative embodiment mutually exclusive with other embodiments. Those skilled in the art explicitly and implicitly understand that the embodiments described herein may be combined with other embodiments.

The technical solutions of the present disclosure will be described in detail below with reference to the accompanying drawings and embodiments.

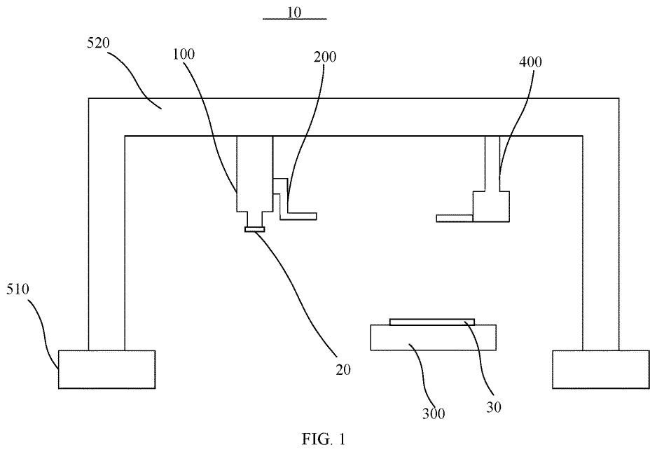

Referring to FIG. 1, FIG. 1 is a schematic structural diagram of a bonding apparatus according to a first implementation of the present disclosure.

As shown in FIG. 1, the bonding apparatus 10 includes: a movable pick-up stage 100, a correction component 200, a carrier stage 300, and an image-acquisition device 400. The movable pick-up stage 100 is configured to pick up and move a first element 20. The correction component 200 is configured to provide a correction mark, and the correction component 200 maintains a fixed distance from the first element 20 or a second element 30. The carrier stage 300 is configured to carry and move the second element 30. The image-acquisition device 400 is configured to read an alignment mark of the first element 20 and the correction mark of the correction component 200, and determine a first relative positional relationship between the first element 20 and the correction component 200 based on the alignment mark of the first element 20 and the correction mark of the correction component 200; and is further configured to read an alignment mark of the second element 30 and the correction mark of the correction component 200, and determine a second relative positional relationship between the second element 30 and the correction component 200 based on the alignment mark of the second element 30 and the correction mark of the correction component 200.

The bonding apparatus 10 determines an alignment offset between the first element 20 and the second element 30 based on the first relative positional relationship and the second relative positional relationship, and based on the alignment offset, drives the movable pick-up stage 100 and/or the carrier stage 300 to perform adjustments for executing an alignment compensation operation, causing the first element 20 and the second element 30 to be aligned and then bonded.

In some embodiments, after the first element 20 and the second element 30 are aligned, it is necessary to drive the movable pick-up stage 100 to move along a height direction, such as moving downward, such that the movable pick-up stage 100 carries the first element 20 to descend and come into contact with the second element 30 for bonding.

In other embodiments, the first element 20 and the second element 30 may be aligned while simultaneously driving the movable pick-up stage 100 to move along the height direction, causing the first element 20 and the second element 30 to contact and bond.

In other embodiments, the first element 20 and the second element 30 may first be driven to a bonding position, and then the first element 20 and the second element 30 may be adjusted to be subjected to the alignment compensation operation.

In some embodiments, the bonding apparatus further includes a machine station 500, and the machine station 500 includes a base 510 and a machine frame 520. The machine frame 520 is disposed on the base 510, the movable pick-up stage 100 is disposed on the machine frame 520, and the carrier stage 300 is disposed below the machine frame 520.

The base 510 may independently support the machine frame 520; or, the base 510 may be an entire supporting surface for supporting the machine frame 520 and the carrier stage 300, meaning the movable pick-up stage 100 is disposed on the machine frame 520 and faces the base 510, and the carrier stage 300 is disposed on the base 510 and faces the machine frame 520.

It should be noted that FIG. 1 only shows one embodiment where the movable pick-up stage 100 is disposed at the top of the machine frame 520 and the carrier stage 300 is disposed on the base 510; in another embodiment, the movable pick-up stage 100 may be disposed on the base 510, and the carrier stage 300 may be disposed on the machine frame 520, specifically to achieve moving the first element 20 and the second element 30 to the bonding position. Therefore, the positions of the movable pick-up stage 100 and the carrier stage 300 are not limited in the present disclosure.

In some embodiments, the correction component 200 is detachably disposed on the movable pick-up stage 100. In response to the bonding apparatus executing the alignment compensation operation, the correction component 200 is configured to be driven to a first position or a second position together with the movable pick-up stage 100, and the image-acquisition device 400 is configured to read the alignment mark of the first element 20 at the first position and the correction mark of the correction component 200 and determine the first relative positional relationship between the first element 20 and the correction component 200, or the image-acquisition device 400 is configured to read the alignment mark of the second element 30 at the second position and the correction mark of the correction component 200 to determine the second relative positional relationship between the second element 30 and the correction component 200. At this time and during subsequent driving processes, the correction component 200 maintains a fixed distance from the first element 20, such as maintaining the first relative positional relationship between the correction component 200 and the first element 20.

The image-acquisition device 400 includes a first field of view and a second field of view. In response to the bonding apparatus executing the alignment compensation operation, the image-acquisition device 400 is configured to recognize the alignment mark of the first element 20 and the correction mark of the correction component 200 via the first field of view, and is configured to recognize the alignment mark of the second element 30 and the correction mark of the correction component 200 via the second field of view.

For example, the image-acquisition device 400 includes a single-perspective image acquisition unit. When recognizing the alignment mark of the first element 20 and the correction mark of the correction component 200, the perspective of the image-acquisition device faces the first element 20 and the correction component 200 at the first position; when recognizing the alignment mark of the second element 30 and the correction mark of the correction component 200, the perspective of the image-acquisition device faces the second element 30 and the correction component 200 at the second position. In some embodiments, the image-acquisition device 400 may be an image acquisition unit with upper and lower perspectives.

The second field of view of the image-acquisition device 400 is simultaneously located in the same direction as the correction component 200 and the first element 20/second element 30. For example, when the second field of view is a downward perspective, the correction component 200, the first element 20, and the second element 30 are aligned vertically downward along the height direction, meaning the horizontal plane height of the image-acquisition device 400 is higher than the horizontal plane heights of the correction component 200, the first element 20, and the second element 30. Because it may be necessary to acquire the alignment mark of the second element 30 through the correction component 200, the correction component 200 may be a transparent, semi-transparent, or perforated calibration sheet.

In some embodiments, the second field of view of the image-acquisition device 400 is simultaneously located between the correction component 200 and the first element 20/second element 30. For example, the image-acquisition device 400 is located between the correction component 200 and the second element 30, then the correction mark of the correction component 200 and the alignment mark of the second element 30 can be acquired respectively, forming them in a single coordinate system. In this case, it is not necessary to realize the acquisition through the correction component 200. Therefore, the correction component 200 may be an opaque plate without perforations, as long as the correction mark on the correction component 200 can be acquired. It is understandable that the first perspective may have a similar setting.

To facilitate the replacement of the correction component 200, the correction component 200 may be detachably installed, for example, detachably disposed on the movable pick-up stage 100 or detachably disposed on the carrier stage 300.

It should be noted that FIG. 1 only shows an embodiment where the correction component 200 is disposed on the movable pick-up stage 100, capable of moving together with the movable pick-up stage 100, entering the first field of view of a first image-acquisition device 410, and entering the second field of view of a second image-acquisition device 420. In other embodiments, the correction component 200 may be fixedly disposed on the machine frame. The movable pick-up stage 100 carries the first element 20 into the first field of view, and the carrier stage 300 carries the second element 30 into the second field of view. In other embodiments, the correction component 200 may be disposed together with the carrier stage 300; the correction component 200 may be disposed on a movable member, which can move into the first field of view and move into the second field of view. Specifically, it is implemented such that the first image-acquisition device 410 can simultaneously acquire the alignment mark of the first element 20 and the correction mark of the correction component 200 within the first field of view, and the second image-acquisition device 420 can simultaneously acquire the alignment mark of the second element 30 and the correction mark of the correction component 200 within the second field of view.

It is understandable that, in some embodiments, the first element 20 may be a wafer to be bonded or a chip to be bonded. Correspondingly, the second element 30 may be a wafer to be bonded or a chip to be bonded.

There is at least one alignment mark on the first element 20. When there are two alignment marks on the first element 20, they are, for example, a first alignment mark B1 and a second alignment mark B2. There is at least one correction mark on the correction component 200. When there are two correction marks on the correction component 200, they are, for example, a first correction mark D1 and a second correction mark D2. There is at least one alignment mark on the second element 30. When there are two alignment marks on the second element 30, they are, for example, a third alignment mark T1 and a fourth alignment mark T2.

Specifically, in response to the bonding apparatus 10 executing a pickup operation, the movable pick-up stage 100 may be driven to reach a pickup position and pick up the first element 20. After confirming that the movable pick-up stage 100 has picked up the first element 20 to be bonded, the movable pick-up stage 100 is driven to the first position. In this case, the correction component 200 follows the movable pick-up stage 100 to the first position. Then, the image-acquisition device 400 recognizes the first alignment mark B1 on the first element 20 and the correction mark D1 on the correction component 200 located within the first field of view at an alignment position, thereby determining the first relative positional relationship between the first element 20 and the correction component 200 within the first field of view.

After determining the first relative positional relationship, the bonding apparatus 10 drives the movable pick-up stage 100 to move to the second position, that is, the movable pick-up stage 100 carries the correction component 200 to the second position. Simultaneously, the carrier stage 300 is driven to carry the second element 30 to the second position, and the image-acquisition device 400 is driven to recognize the third alignment mark T1 on the second element 30 and the first correction mark D1 on the correction component 200 located within the second field of view at the bonding position. Because the first correction mark D1 and the third alignment mark T1 are now within the second field of view, the second relative positional relationship between the second element 30 and the correction component 200 is determined within the second field of view.

The first position may be a position where the first element 20 and the correction component 200 are located when acquiring the alignment mark of the first element 20 and the correction mark of the correction component 200. The second position may be a position where the second element 30 and the correction component 200 are located when acquiring the alignment mark of the second element 30 and the correction mark of the correction component 200.

In some embodiments, there may be at least two correction marks on the correction component 200, and there may be at least two alignment marks on each of the first element 20 and the second element 30. For example, the first correction mark D1 and the second correction mark D2 can more clearly represent the positional relationship between the first correction mark D1 and the second correction mark D2 and the positional relationship between the first alignment mark B1 and the second alignment mark B2 of the first element, respectively, as well as the positional relationship between the correction mark D1 and the second correction mark D2 and the positional relationship between the third alignment mark T1 and the fourth alignment mark T2, and determine the offset between the first alignment mark B1 and the second alignment mark B2 and the offset between the third alignment mark T1 and the fourth alignment mark T2.

After obtaining the first relative positional relationship and the second relative positional relationship, using the correction component 200 as a reference, the alignment offset between the first element 20 and the second element 30 may be determined based on the first relative positional relationship and the second relative positional relationship. Then, based on the alignment offset, the movable pick-up stage 100 and/or the carrier stage 300 are driven to perform adjustments for executing the alignment compensation operation. That is, the movable pick-up stage 100 and/or the carrier stage 300 are driven to perform the alignment compensation operation at the bonding position, aligning the first element 20 and the second element 30. Then, the movable pick-up stage 100 is driven to carry the first element 20 to move along the height direction, such as moving downward, such that the aligned first element 20 and second element 30 are bonded.

That is, it is only necessary to obtain the first relative positional relationship between the first element 20 and the correction component 200 once, and the second relative positional relationship between the second element 30 and the correction component 200 once. Then, based on the first relative positional relationship and the second relative positional relationship, the alignment offset between the first element 20 and the second element 30 can be determined. Based on this alignment offset, the alignment between the first element 20 and the second element 30 can be completed in one go, which may avoid the long time consumption caused by repeatedly performing operations like alignment, measurement, adjustment, and re-alignment measurement.

The pickup position may be a position where the movable pick-up stage 100 can pick up the first element 20. The alignment position may be a position corresponding to the first image-acquisition device 410 acquiring the first alignment mark B1 and the second alignment mark B2 on the first element 20 when it is at the first position, and the first correction mark D1 and second correction mark D2. The bonding position may be a position corresponding to the second image-acquisition device 420 acquiring the third alignment mark T1 and the fourth alignment mark T2 on the second element 30 when it is at the second position, and the correction mark D1. The bonding position may be also the position to perform the alignment compensation operation on the movable pick-up stage 100 and/or the carrier stage 300, as well as the position to perform the bonding operation on the first element 20 and the second element 30. In some embodiments, when the first element 20 and the second element 30 are at the bonding position, the alignment marks of the first element 20 and the alignment marks of the second element 30 are roughly aligned one by one.

In the embodiments, by setting a correction component for reference, the first relative positional relationship between the first element and the correction component is obtained, and the second relative positional relationship between the second element and the correction component is obtained. Then, based on the first relative positional relationship and the second relative positional relationship, the alignment offset between the first element and the second element is determined. This may allow the bonding apparatus to complete the alignment and bonding of the first element and the second element based on the alignment offset. In addition, it may not be necessary to perform multiple alignments for each second element to be bonded, thereby effectively shortening the time consumption, helping to improve bonding efficiency, and increasing yield.

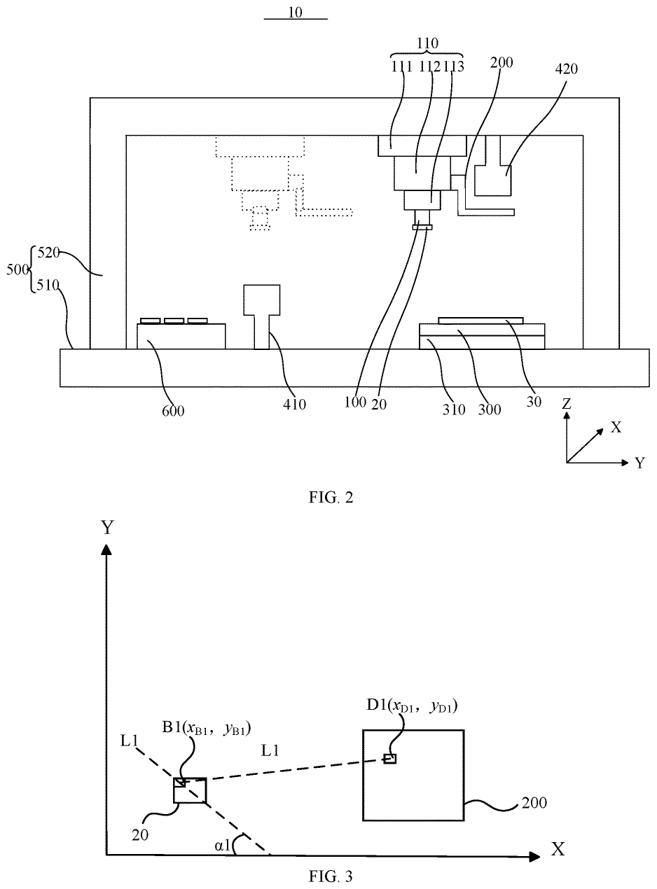

Referring to FIG. 2, FIG. 2 is a schematic structural diagram of a bonding apparatus according to a first implementation of the present disclosure. As shown in FIG. 2, the bonding apparatus 10 includes: a movable pick-up stage 100, a correction component 200, a carrier stage 300, an image-acquisition device 400, and a machine station 500. The machine station 500 includes a base 510 and a machine frame 520. The machine frame 520 is disposed on the base 510, the movable pick-up stage 100 is disposed on the machine frame 520 and faces the base 510. The image-acquisition device 400 may include a first image-acquisition device 410 and a second image-acquisition device 420. The first image-acquisition device 410 may be disposed on the base 510 and face the machine frame 520. The second image-acquisition device 420 may be disposed on the machine frame 520 and face the base 510. The carrier stage 300 is disposed on the base 510.

The movable pick-up stage 100 is configured to be movable along the X-direction, Y-direction in the horizontal plane, and the height direction Z, and can rotate in a vertical plane perpendicular to the horizontal plane. That is, the movable pick-up stage 100 can carry the first element 20 and the correction component 200 to move along the X-direction, Y-direction, and height direction Z, and can rotate in the vertical plane perpendicular to the horizontal plane. The carrier stage 300 is configured to be movable along the X-direction, Y-direction in the horizontal plane, and the height direction Z, and can rotate in the vertical plane perpendicular to the horizontal plane. That is, the carrier stage 300 can carry the second element 30 to move along the X-direction, Y-direction, and height direction Z, and can rotate in the vertical plane perpendicular to the horizontal plane. The first image-acquisition device 410 is disposed on the base 510 and corresponds to a first position. The second image-acquisition device 420 is disposed on the machine frame 520 and corresponds to a second position.

It should be noted that FIG. 2 only shows an embodiment where the correction component 200 is disposed on the movable pick-up stage 100, maintaining a fixed distance from the first element 20. In another embodiment, the correction component 200 may be disposed on the carrier stage 300, maintaining a fixed distance from the second element 30. Or, the correction component 200 can move synchronously with the movable pick-up stage 100 or the carrier stage 300. Specifically, it is implemented such that the correction component 200 maintains a fixed distance from the first element 20, or the correction component 200 maintains a fixed distance from the second element 30.

It should be noted that FIG. 2 only shows an embodiment where the first image-acquisition device 410 is disposed on the base 510 and the second image-acquisition device 420 is disposed on the machine frame 520. In another embodiment, the first image-acquisition device 410 may be suspended from the machine frame 520, and the second image-acquisition device 420 can be disposed on the base 510. Specifically, it is implemented such that the first image-acquisition device 410 can acquire the alignment mark of the first element 20 and the correction mark of the correction component 200, and the second image-acquisition device 420 can acquire the alignment mark of the second element 30 and the correction mark of the correction component 200. Therefore, the positions of the first image-acquisition device 410 and the second image-acquisition device 420 are not limited in the present disclosure.

The X-direction and Y-direction may be intersecting directions within the same horizontal plane. For example, the X-direction and Y-direction are perpendicular within the same horizontal plane. The height direction Z may be a direction perpendicular to the horizontal plane.

In some embodiments, the movable pick-up stage 100 may be a pick-up member capable of flipping. That is, it flips after picking up the first element 20 at the pickup position, causing a bonding surface of the first element 20 to face upward. After reaching the bonding position, the pick-up member flips again, causing the bonding surface of the first element 20 to face the second element 30, thereby preventing damage to the bonding surface of the first element 20 during movement.

In some embodiments, a bottom of the base 510 may be arranged with a vibration isolation and damping device to eliminate vibrations caused by the movement of the carrier stage 300 carrying the second element 30 to be bonded and during the bonding operation, thereby improving the stability of the bonding apparatus 10.

In some embodiments, the first image-acquisition device 410 includes at least one first image acquisition unit, where the first image acquisition unit is an upward-looking image acquisition unit. Taking one correction mark and one alignment mark as an example, in response to the movable pick-up stage 100 being driven to the first position, the upward-looking image acquisition unit is configured to recognize the first alignment mark B1 on the first element 20 carried by the movable pick-up stage 100 at the first position, and the correction mark D1 on the correction component 200. Furthermore, because the first alignment mark B1 and the correction mark D1 are both within the first field of view, a first coordinate system can be established based on the first alignment mark B1 and the correction mark D1, and the coordinate information of each mark in the first coordinate system can be determined, thereby determining the first relative positional relationship between the first element 20 and the correction component 200.

The upward-looking image acquisition unit may be one or multiple. When a single upward-looking image acquisition unit cannot simultaneously acquire the first alignment mark B1 of the first element and the correction mark of the correction component 200, or cannot simultaneously acquire multiple alignment marks and multiple correction marks, then two or more upward-looking image acquisition units may be set to meet the requirement of simultaneously acquiring the first alignment mark B1 of the first element and the correction mark of the correction component 200.

The first coordinate system includes an X-axis and a Y-axis. In the first coordinate system, the coordinate information of the first alignment mark B1 on the first element 20 is B1 (x_{B1}, y_{B1}), and the coordinate information of the correction mark D1 on the correction component 200 is D1 (x_{D1}, y_{D1}).

Taking two correction marks and two alignment marks as an example, the first coordinate system includes an X-axis and a Y-axis, and in the first coordinate system, the coordinate information of the first alignment mark B1 on the first element 20 is B1 (x_{B1}, y_{B1}), the coordinate information of the second alignment mark B2 is B2 (x_{B2}, y_{B2}), the coordinate information of the first correction mark D1 on the correction component 200 is D1 (x_{D1}, y_{D1}), and the coordinate information of the second correction mark D2 is D2 (x_{D2}, y_{D2}).

In some embodiments, the second image-acquisition device 420 includes at least one second image acquisition unit, and the second image acquisition unit is a downward-looking image acquisition unit. In response to the bonding apparatus executing the alignment compensation operation, the carrier stage 300 is driven to the second position, and the movable pick-up stage 100 is driven to carry the correction component 200 to the second position. Then, the downward-looking image acquisition unit is configured to recognize the second alignment mark T1 on the second element 30 at the second position, and to recognize the correction mark D1 on the correction component 200. Furthermore, because the second alignment mark T1 and the first correction mark D1 are both within the second field of view, a second coordinate system can be established based on the second alignment mark T1 and the correction mark D1, and the coordinate information of each mark in the second coordinate system can be determined, thereby determining the second relative positional relationship between the second element 30 and the correction component 200.

The second coordinate system includes an X-axis and a Y-axis. In the second coordinate system, the coordinate information of the second alignment mark T1 on the second element 30 is T1 (x_{T1}, y_{T1}), and the coordinate information of the correction mark D1 on the correction component 200 is D3 (x_{D3}, y_{D3}).

When both the correction marks and alignment marks are two, the second coordinate system includes an X-axis and a Y-axis, and in the second coordinate system, the coordinate information of the second alignment mark T1 on the second element 30 is T1 (x_{T1}, y_{T1}), the coordinate information of the fourth alignment mark T2 is T2 (x_{T2}, y_{T2}), the coordinate information of the first correction mark D1 on the correction component 200 is D3 (x_{D3}, y_{D3}), and the coordinate information of the second correction mark D2 is D4 (x_{D4}, y_{D4}).

In some embodiments, in response to the bonding apparatus 10 executing the bonding operation, the bonding apparatus adjusts the movable pick-up stage 100 and/or the carrier stage 300 based on the alignment offset to perform the alignment compensation operation on the first element 20 and the second element 30 at the second position. Then, the movable pick-up stage 100 and/or the carrier stage 300 are moved in the height direction to drive the first element 20 and the second element 30 to the bonding position.

In response to the bonding apparatus 10 executing the bonding operation, the bonding apparatus 10 may move the movable pick-up stage 100 and/or the carrier stage 300 in the height direction to drive the first element 20 and the second element 30 to the bonding position, while simultaneously adjusting the movable pick-up stage 100 and/or the carrier stage 300 based on the alignment offset to perform the alignment compensation operation on the first element 20 and the second element 30.

The bonding position may be a position where the first element 20 and the second element 30 are bonded.

In some embodiments, the bonding apparatus 10 further includes a first drive assembly 110 and a second drive assembly 310. The first drive assembly 110 is disposed on the machine frame 520 and connected to the movable pick-up stage 100. The first drive assembly 110 is configured to carry the movable pick-up stage 100 to be movable along the X-direction, Y-direction in the horizontal plane, and the height direction, and to be rotatable in the vertical plane perpendicular to the horizontal plane. The second drive assembly 310 is disposed on the base 510 and connected to the carrier stage 300. The second drive assembly 310 is configured to carry the carrier stage 300 to be movable along the X-direction, Y-direction in the horizontal plane, and the height direction Z, and to be rotatable in the vertical plane perpendicular to the horizontal plane.

Further, the first drive assembly 110 may include a first driving member 111, a second driving member 112, and a third driving member 113.

Specifically, the first driving member 111 is movably disposed on the machine frame 520 and faces the base 510. The second driving member 112 is connected to the first driving member 111 and faces the base 510. The third driving member 113 is connected to the second driving member 112 and the movable pick-up stage 100 respectively. That is, an upper part of the third driving member 113 is connected to the second driving member 112, and a lower part of the third driving member 113 is connected to the movable pick-up stage 100. The movable pick-up stage 100 and the third driving member 113 may be detachably connected, allowing for timely replacement in case of failure. The first driving member 111 is configured to carry the second driving member 112, the third driving member 113, and the movable pick-up stage 100 to move along the X-direction and Y-direction in the horizontal plane. The second driving member 112 is configured to carry the third driving member 113 and the movable pick-up stage 100 to move along the height direction. The third driving member 113 is configured to carry the movable pick-up stage 100 to rotate in the rotational direction of the horizontal plane.

In some embodiments, to facilitate timely replacement in case of failure, the first driving member 111 may be detachably disposed on the machine frame 520; the second driving member 112 and the first driving member 111 may be detachably connected; the third driving member 113 and the second driving member 112 may be detachably connected.

In some embodiments, the first driving member 111 may be an X/Y-axis macro-motion drive member, configured to achieve movement of the first driving member 111 along the X-direction and Y-direction in the horizontal plane, and perform nano-level coarse positioning. The second driving member 112 may be a Z-axis drive member, configured to achieve movement of the second driving member 112 driving the movable pick-up stage 100 in the height direction. The third driving member 113 can be a rotational drive member, used to achieve rotation of the third driving member 113 driving the movable pick-up stage 100 in a vertical plane perpendicular to the horizontal plane, and achieve micro-radian level positioning accuracy for the movable pick-up stage 100.

Further, the second drive assembly 310 may be an X/Y-axis high-precision motion drive member, movably disposed on the base 510. The carrier stage 300 is disposed on the second drive assembly 310. The second drive assembly 310 is configured to carry the carrier stage 300 to move along the X-direction and Y-direction in the horizontal plane. That is, the second drive assembly 310 can drive the carrier stage 300 to move on the base 510, performing nano-level coarse positioning, such that the second element 30 on the carrier stage 300 aligns with the first element 20 picked up by the movable pick-up stage 100.

It should be noted that the first driving member 111, the second driving member 112, the third driving member 113, and the second drive assembly 310 may each include: a motor, such as linear motors or rotary motors, to provide power for a corresponding drive member. It is understandable that the structural design of the first driving member 111 in the embodiments of the present disclosure may refer to specific structures in the related art, as long as it can achieve the function of moving the movable pick-up stage 100 within the horizontal plane along the X-direction and Y-direction and achieve nano-level precision positioning. The present disclosure does not impose specific restrictions. Correspondingly, the structural designs of the second driving member 112, the third driving member 113, and the second drive assembly 310 may refer to specific structures in the related art, as long as they can achieve their corresponding functions.

In some embodiments, the X-direction, the Y-direction, and the Z-direction (height direction) are mutually perpendicular to each other. Specifically, the Y-direction may be a direction parallel to the Y-axis, the X-direction may be a direction parallel to the X-axis, and the Z-direction may be a direction parallel to the Z-axis. Correspondingly, the first driving member 111 is referred to as an X/Y-axis macro-motion drive member. The second driving member 112 and the third driving member 113 may be referred to as a Z-axis drive member and a rotational drive member, respectively. The second drive assembly 310 may be referred to as an X/Y high-precision motion drive member.

In some embodiments, the carrier stage 300 may be a single-stage motion mechanism or other types of motion mechanisms, as long as it can move the second element 30 to be bonded to a predetermined surface position corresponding to the first element 20 to be bonded and bond it to the predetermined surface position of the first element 20 to be bonded while meeting specific accuracy requirements.

In some embodiments, the bonding apparatus 10 may further include a supply platform 600. The supply platform 600 is disposed on the base 510 and is configured to provide the first element 20 to be bonded to the movable pick-up stage 100. That is, multiple first elements 20 to be bonded are placed on the supply platform 600. The movable pick-up stage 100 may pick up the first element 20 on the supply platform 600 at the pickup position, then carry the first element 20 to the alignment position, enabling the first image-acquisition device 410 to acquire the first alignment mark B1 on the first element 20 and the correction mark D1 on the correction component 200.

The operation process of the bonding apparatus 10 is described below.

Specifically, the first image-acquisition device 410 has a first perspective and is configured to read at least one alignment mark on the first element 20 to be bonded and at least one correction mark on the correction component 200 at the alignment position. The second image-acquisition device 420 has a second perspective and is configured to read at least one alignment mark on the second element 30 to be bonded and at least one correction mark on the correction component 200 at the alignment position. Taking the first element having a first alignment mark B1, the correction component 200 having a correction mark D1, and the second element 30 having a third alignment mark T1 as an example for description.

In response to determining the alignment offset between the first element 20 and the second element 30, the correction mark of the correction component 200 maintains a first relative positional relationship with the alignment mark of the first element 20. The first element 20 is driven to the second position. The image-acquisition device 400 is configured to recognize the alignment mark of the second element 30 and the correction mark of the correction component 200, obtaining the offset between the alignment mark of the first element 20 and the alignment mark of the second element 30 as the alignment offset to execute the alignment compensation operation. Or, in response to determining the alignment offset between the first element 20 and the second element 30, the correction mark of the correction component 200 maintains a second relative positional relationship with the alignment mark of the second element 30. The first element 20 is driven to the second position. The image-acquisition device 400 is configured to recognize the alignment mark of the first element 20 and the correction mark of the correction component 200, obtaining the offset between the alignment mark of the first element 20 and the alignment mark of the second element 30 as the alignment offset to execute the alignment compensation operation.

Furthermore, in response to the bonding apparatus executing the bonding operation, the bonding apparatus adjusts the movable pick-up stage 100 and/or the carrier stage 300 based on the alignment offset to perform an alignment compensation operation on the first element 20 and the second element 30 at the second position. Then, the movable pick-up stage 100 and/or the carrier stage 300 are moved in the height direction to drive the first element 20 and the second element 30 to the bonding position. Alternatively, in response to the bonding apparatus executing the bonding operation, the bonding apparatus moves the movable pick-up stage 100 and/or the carrier stage 300 in the height direction to drive the first element 20 and the second element 30 to the bonding position, while simultaneously adjusting the movable pick-up stage 100 and/or the carrier stage 300 based on the alignment offset to perform the alignment compensation operation on the first element 20 and the second element 30. Alternatively, in response to the bonding apparatus executing the bonding operation, the bonding apparatus moves the movable pick-up stage 100 and/or the carrier stage 300 in the height direction to drive the first element 20 and the second element 30 to the bonding position, and then, based on the alignment offset, adjusts the movable pick-up stage 100 and/or the carrier stage 300 to perform the alignment compensation operation on the first element 20 and the second element 30.

The supply platform 600 and the first image-acquisition device 410 are disposed on the base 510. When executing a bonding task, the bonding apparatus 10 drives the first drive assembly 110 to carry the movable pick-up stage 100 to the pickup position corresponding to the supply platform 600, and drives the second driving member 112 to move the movable pick-up stage 100 in the height direction, such as moving it down, such that the movable pick-up stage 100 picks up the first element 20 to be bonded. Then, it drives the movable pick-up stage 100 to move to the alignment position, which is the mark recognition position corresponding to the first image-acquisition device 410. The correction component 200 moves together with the movable pick-up stage 100. Therefore, the first image-acquisition device 410 can recognize the first alignment mark B1 on the first element 20 and the first correction mark D1 on the correction component 200 within the first camera field of view, establish a first coordinate system, and then determine the coordinate information of each mark in the first coordinate system.

Referring to FIG. 3, FIG. 3 is a schematic diagram of a first coordinate system of one correction mark corresponding to a bonding apparatus according to some embodiments of the present disclosure.

As shown in FIG. 3, the first coordinate system includes an X-axis and a Y-axis. The coordinate information of the first alignment mark B1 in the first coordinate system is determined as B1 (x_{B1}, y_{B1}), and the coordinate information of the first correction mark D1 is D1 (x_{D1}, y_{D1}). Based on the difference in coordinate information, the first relative positional relationship between the first element 20 and the correction component 200 is determined.

Continuing to refer to FIG. 3, in the first coordinate system, a first line connecting the first alignment mark B1 of the first element 20 to be bonded and the first correction mark D1 of the correction component 200 is defined as L1. Based on the distance relationship of the first line L1 and the angular relationship between the first line L1 and the X-axis and Y-axis, the first relative positional relationship between the first element 20 and the correction component 200 may be determined.

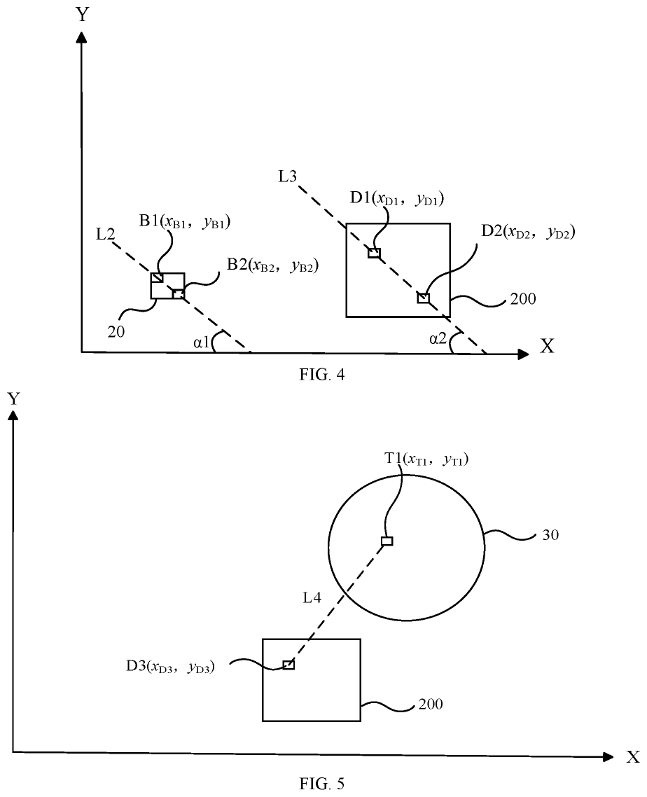

Referring to FIG. 4, FIG. 4 is a schematic diagram of a first coordinate system of two correction marks corresponding to a bonding apparatus according to some embodiments of the present disclosure.

As shown in FIG. 4, the first coordinate system includes an X-axis and a Y-axis. The coordinate information of the first alignment mark B1 in the first coordinate system is determined as B1 (x_{B1}, y_{B1}), the coordinate information of the second alignment mark B2 is B2 (x_{B2}, y_{B2}), the coordinate information of the first correction mark D1 is D1 (x_{D1}, y_{D1}), and the coordinate information of the second correction mark D2 is D2 (x_{D2}, y_{D2}). Based on the difference in coordinate information, the first relative positional relationship between the first element 20 and the correction component 200 is determined.

Continuing to refer to FIG. 4, in the first coordinate system, a second line connecting the first alignment mark B1 and the second alignment mark B2 of the first element 20 to be bonded is defined as L2. A first angle between the second line L2 and the X-axis direction in the first coordinate system is α1. A third line connecting the first correction mark D1 and the second correction mark D2 of the correction component 200 is defined as L3. A second angle between the third line L3 and the X-axis direction in the first coordinate system is α2. Then, a first angular deviation Δα1 between the first element 20 to be bonded and the correction component 200 in the first coordinate system is the difference between the first angle α1 and the second angle α2, i.e., Δα1 is the absolute value of (α2−α1).

Specifically, after acquiring the coordinate information of the first alignment mark B1 and the second alignment mark B2 of the first element 20, and the first correction mark D1 and the second correction mark D2 of the correction component 200, a difference calculation is performed. That is, a first X-axis difference Δx1 between B1 and D1 on the X-axis is obtained, where Δx1=the absolute value of (x_{B1}−x_{D1}). A second X-axis difference Δx2 between B2 and D2 on the X-axis is obtained, where Δx2=the absolute value of (x_{B2}−x_{D2}). A first Y-axis difference Δy1 between B1 and D1 on the Y-axis is obtained, where Δy1 =the absolute value of (y_{B1}−y_{D1}). A second Y-axis difference Δy2 between B2 and D2 on the Y-axis is obtained, where Δy2=the absolute value of (y_{B2}−y_{D2}). The first angular deviation value Δα1 between the second line L2 and the third line L3 is obtained, where Δα1=the absolute value of (α2−α1). Then, based on the first X-axis difference Δx1, the second X-axis difference Δx2, the first Y-axis difference Δy1, the second Y-axis difference Δy2, and the first angular deviation Δα1, the first relative positional relationship between the first element 20 and the correction component 200 may be determined.

After determining the first relative positional relationship, the bonding apparatus 10 may drive the carrier stage 300 to carry the second element 30 to the second position, and simultaneously drive the movable pick-up stage 100 to carry the correction component 200 to the second position, which is a position corresponding to the second image-acquisition device 420 at the alignment position. Then, the second image-acquisition device 420 is driven to recognize the third alignment mark T1 on the second element 30 and the first correction mark D1 on the correction component 200 within the second field of view, establish a second coordinate system, and then determine the coordinate information of each mark in the second coordinate system.

Referring to FIG. 5, FIG. 5 is a schematic diagram of a second coordinate system of one correction mark corresponding to a bonding apparatus according to some embodiments of the present disclosure.

As shown in FIG. 5, the second coordinate system includes an X-axis and a Y-axis. The coordinate information of the third alignment mark T1 in the second coordinate system is determined as T1 (x_{T1}, y_{T1}), and the coordinate information of the correction mark D1 is D3 (x_{D3}, y_{D3}). Based on the difference in coordinate information, the second relative positional relationship between the second element 30 and the correction component 200 is determined.

Continuing to refer to FIG. 5, in the second coordinate system, the fourth line connecting the third alignment mark T1 of the second element 30 to be bonded and the first correction mark D1 of the correction component 200 is defined as L4. Based on the distance relationship of the fourth line L4 and the angular relationship between the fourth line L4 and the X-axis and Y-axis, the second relative positional relationship between the second element 30 and the correction component 200 may be determined.

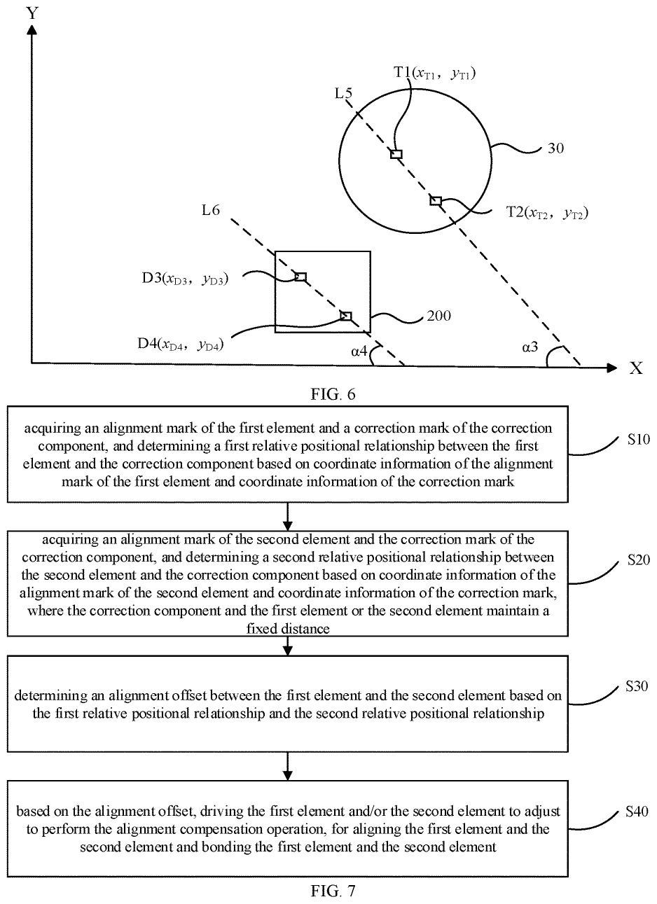

Referring to FIG. 6, FIG. 6 is a schematic diagram of a coordinate system of two correction marks corresponding to a bonding apparatus according to some embodiments of the present disclosure.

As shown in FIG. 6, the second coordinate system includes an X-axis and a Y-axis. The coordinate information of the third alignment mark T1 in the second coordinate system is determined as T1 (x_{T1}, y_{T1}), the coordinate information of the fourth alignment mark T2 is T2 (x_{T2}, y_{T2}), the coordinate information of the first correction mark D1 is D3 (x_{D3}, y_{D3}), and the coordinate information of the second correction mark D2 is D4 (x_{D4}, y_{D4}). Based on the difference in coordinate information, the second relative positional relationship between the second element 30 and the correction component 200 is determined.

Continuing to refer to FIG. 6, in the second coordinate system, a fifth line connecting the third alignment mark T1 and the fourth alignment mark T2 of the second element 30 to be bonded is defined as L5. A third angle between the fifth line L5 and the X-axis direction in the second coordinate system is α3. A sixth line connecting the first correction mark D1 and the second correction mark D2 of the correction component 200 is defined as L6. A fourth angle between the sixth line L6 and the X-axis direction in the second coordinate system is α4. Then, a second angular deviation Δα2 between the second element 30 to be bonded and the correction component 200 in the second coordinate system is the difference between the third angle α3 and the fourth angle α4, i.e., Δα2 is the absolute value of (α4−α3).

Specifically, after acquiring the coordinate information of the third alignment mark T1 and the fourth alignment mark T2 of the second element 30, and the first correction mark D1 and the second correction mark D2 of the correction component 200 in the second coordinate system, a difference calculation is performed. That is, a third X-axis difference Δx3 between T1 and D1 on the X-axis is obtained, where Δx3=the absolute value of (x_{T1}−x_{D3}). A fourth X-axis difference Δx4 between T2 and D2 on the X-axis is obtained, where Δx4=the absolute value of (x_{T2}−x_{D4}). A third Y-axis difference Δy3 between T1 and D1 on the Y-axis is obtained, where Δy3=the absolute value of (y_{T1}−y_{D3}). A fourth Y-axis difference Δy4 between T2 and D2 on the Y-axis is obtained, where Δy4=the absolute value of (y_{T2}−y_{D4}). The second angular deviation value Δα2 between the fifth line L5 and the sixth line L6 is obtained, where Δα2=the absolute value of (α4−α3). Then, based on the third X-axis difference Δx3, the fourth X-axis difference Δx4, the third Y-axis difference Δy3, the fourth Y-axis difference Δy4, and the second angular deviation Δα2, the second relative positional relationship between the second element 30 and the correction component 200 may be determined.

Then, using the first correction mark D1 of the correction component 200 as a reference, the first coordinate system and the second coordinate system are merged into a bonding coordinate system. That is, the coordinate information D1 (x_{D1}, y_{D1}) of the first correction mark D1 in the first coordinate system is equal to the coordinate information D3 (x_{D3}, y_{D3}) in the second coordinate system. Consequently, the coordinate information of the first alignment mark B1 of the first element 20 and the third alignment mark T1 of the second element 30 in the bonding coordinate system is obtained. Then, based on a difference calculation of the coordinate information, the alignment offset between the first element 20 and the second element 30 can be determined. Therefore, based on the alignment offset, the movable pick-up stage 100 and/or the carrier stage 200 can be adjusted to perform the alignment compensation operation, aligning the first element 20 and the second element 30, and then bonding them. In other words, the alignment offset between the first element 20 and the second element 30 is determined, and based on this alignment offset, the alignment between the first element 20 and the second element 30 can be completed in one go, thereby avoiding the time-consuming problem caused by multiple alignments.

Similarly, when the correction component 200 has multiple correction marks, and the first element 20 and the second element 30 have multiple alignment marks, the first coordinate system and the second coordinate system may be merged into a bonding coordinate system using the above method.

In the embodiments, by using the correction component as a reference, the first relative positional relationship between the first element 20 and the correction component 200 is obtained, and the second relative positional relationship between the second element 30 and the correction component 200 is obtained. Then, based on the first relative positional relationship and the second relative positional relationship, the alignment offset between the first element 20 and the second element 30 is determined. This may enable the bonding apparatus to complete the alignment and bonding of the first element 20 and the second element 30 based on the alignment offset. In addition, it may eliminate the need for multiple alignments for each second element to be bonded, effectively shortening the time consumption, which helps improve bonding efficiency and yield.

Furthermore, in the present disclosure, the marks of the first element 20 and the correction component 200 are acquired within the first field of view, and the marks of the second element 30 and the correction component 200 are acquired within the second field of view. The distribution of the alignment marks of the first element 20 to be bonded and the second element 30 to be bonded is not limited. Therefore, the impact of the camera's field of view size restrictions on the alignment marks of the first element 20 to be bonded and the second element 30 to be bonded may be effectively reduced.

Furthermore, in the bonding apparatus of the present disclosure, through the cooperation of the first drive assembly 110 and the second drive assembly 310, a motion closed-loop may be formed, enabling the carrier stage to achieve nano-level precision positioning, thereby effectively improving bonding accuracy.

It is understandable that the bonding apparatus in the embodiments of the present disclosure may be applied not only to chip-to-wafer (C2W) bonding technology, i.e., in the bonding apparatus described in the above embodiments, the machine frame 520, the base 510, the carrier stage 300, and the movable pick-up stage 100 in the machine station 500 cooperate to form a high-precision moving platform and create a motion closed-loop, thereby moving the chip to be bonded to the predetermined surface position of the wafer to be bonded and bonding it to the predetermined surface position of the wafer to be bonded. In some embodiments, the bonding apparatus in the embodiments of the present disclosure may also be applied to wafer-to-wafer (W2W) bonding technology, i.e., in the bonding apparatus described in the above embodiments, the machine frame 520, the base 510, the carrier stage 300, and the movable pick-up stage 100 in the machine station 500 cooperate to form a high-precision moving platform and create a motion closed-loop, thereby moving the first wafer to be bonded to the predetermined surface position of the second wafer to be bonded and bonding it to the predetermined surface position of the second wafer to be bonded. Its working principle and the technical effects to be achieved may be basically the same as those applied to chip-to-wafer (C2W) bonding technology, and specific details can be referred to in the relevant descriptions in the above embodiments. Similarly, the bonding apparatus in the embodiments of the present disclosure may also be applied to chip-to-chip (C2C) bonding technology, and its working principle and the technical effects to be achieved may be basically the same as those applied to chip-to-wafer (C2W) bonding technology, and specific details can be referred to in the relevant descriptions in the above embodiments.

Based on the above bonding apparatus, the method for bonding the second element 30 and the first element 20 using the above bonding apparatus is described below.

Referring to FIG. 7, FIG. 7 is a schematic flowchart of a bonding method according to some embodiments of the present disclosure. The operations of the bonding method provided in the embodiments of the present disclosure are described in detail below with reference to the figure.

Specifically, as shown in FIG. 7, the bonding method may be applied to the bonding apparatus in any of the above embodiments. The bonding method includes the following operations at blocks illustrated herein.

At block S10: acquiring an alignment mark of the first element and a correction mark of the correction component, and determining a first relative positional relationship between the first element and the correction component based on coordinate information of the alignment mark of the first element and coordinate information of the correction mark.

In some embodiments, the operation flow of S10 is as follows.

In response to the bonding apparatus executing a bonding operation, the movable pick-up stage of the bonding apparatus is driven to pick up the first element; the movable pick-up stage of the bonding apparatus is driven to a first position, and the image-acquisition device of the bonding apparatus is used to recognize the alignment mark of the first element and the correction mark of the correction component; the first relative positional relationship is determined based on the coordinate information of the alignment mark of the first element and the coordinate information of the correction mark.

To reduce multiple alignment operations, the alignment mark of the first element and the correction mark of the correction component are required to be acquired in advance within the first field of view; the correction component may be a transparent, semi-transparent, or perforated calibration sheet.

Specifically, the bonding apparatus 10 may drive the movable pick-up stage 100 to move to a pickup position, and pick up the first element 20 to be bonded on the supply platform 600 by driving the second driving member 112 to move the movable pick-up stage 100 in the height direction, such as moving it down. After picking up the first element 20 to be bonded, the bonding apparatus 10 may drive the second driving member 112 to move the movable pick-up stage 100 in the height direction, such as moving it up, and drive the first driving member 111 to carry the movable pick-up stage 100 to the first position. Then, the image-acquisition device 400 at an alignment position may recognize the first alignment mark B1 of the first element 20 and the first correction mark D1 of the correction component 200 within the first field of view, establish a first coordinate system based on the first alignment mark B1 and the first correction mark D1, and acquire the coordinate information of each mark in the first coordinate system. In the first coordinate system, the coordinate information of the first alignment mark B1 is B1 (x_{B1}, y_{B1}), and the coordinate information of the first correction mark D1 is D1 (x_{D1}, y_{D1}).

Continuing to refer to FIG. 3, in the first coordinate system, a first line connecting the first alignment mark B1 of the first element 20 to be bonded and the first correction mark D1 of the correction component 200 is defined as L1. Based on the distance relationship of the first line L1, the first relative positional relationship between the first element 20 and the correction component 200 may be determined. In some embodiments, the first relative positional relationship between the first element 20 and the correction component 200 may be further precisely determined based on an angular relationship between the first line L1 and the X-axis and Y-axis.

In a case where the first element 20 and the correction component 200 have multiple alignment marks and correction marks respectively, the first relative positional relationship between the first element 20 and the correction component 200 may be determined based on the coordinate relationship shown in FIG. 4.

At block S20: acquiring an alignment mark of the second element and the correction mark of the correction component, and determining a second relative positional relationship between the second element and the correction component based on coordinate information of the alignment mark of the second element and coordinate information of the correction mark, where the correction component and the first element or the second element maintain a fixed distance.

In some embodiments, the operation flow of S20 is as follows.

In response to the bonding apparatus executing a bonding operation, the carrier stage of the bonding apparatus is driven to a second position, and the movable pick-up stage to carry the correction component is driven to the second position. The image-acquisition device of the bonding apparatus is used to recognize the alignment mark of the second element and the correction mark of the correction component; determine the second relative positional relationship based on the coordinate information of the alignment mark of the second element and the coordinate information of the correction mark.

Before bonding, alignment is required. To avoid multiple alignments, the alignment mark of the second element and the correction mark of the correction component need to be acquired in advance to determine the second relative positional relationship between the second element and the correction component. Alternatively, to speed up bonding, alignment and bonding may be performed simultaneously.

Specifically, after obtaining the first relative positional relationship, the carrier stage 300 may be driven to carry the second element 30 to be bonded to the second position, and the first driving member 111 may be driven to carry the movable pick-up stage 100 carrying the correction component 200 to the second position. Then, the second image-acquisition device 420 may recognize the third alignment mark T1 of the second element 30 and the first correction mark D1 of the correction component 200 within the second field of view, establish a second coordinate system based on the third alignment mark T1 and the first correction mark D1, and acquire the coordinate information of each mark in the second coordinate system. In the second coordinate system, the coordinate information of the third alignment mark is T1 (x_{T1}, y_{T1}), and the coordinate information of the first correction mark D1 is D3 (x_{D3}, y_{D3}). Then, based on the difference in coordinate information, the second relative positional relationship between the second element 30 and the correction component 200 is determined.

Continuing to refer to FIG. 5, in the second coordinate system, the fourth line connecting the third alignment mark T1 of the second element 30 to be bonded and the first correction mark D1 of the correction component 200 is defined as L4. Based on the distance relationship of the fourth line L4, the second relative positional relationship between the second element 30 and the correction component 200 can be determined. Further, the second relative positional relationship between the second element 30 and the correction component 200 may be more precisely determined based on the angular relationship between the fourth line L4 and the X-axis and Y-axis.

In some embodiments, in response to the bonding apparatus executing an alignment compensation operation, the correction component 200 is driven to the second position, and the image-acquisition device 400 of the bonding apparatus is used to recognize the alignment mark of the second element 30 and the correction mark of the correction component 200, to obtain a difference between the alignment mark of the first element 20 and the alignment mark of the second element 30 as an alignment offset, and execute the alignment compensation operation. Here, the correction mark of the correction component 200 may maintain the first relative positional relationship with the alignment mark of the first element 20.

In some embodiments, the first element 20 and the second element 30 are moved to the second position via the movable pick-up stage and/or the carrier stage, and the alignment compensation operation is executed to align the first element 20 and the second element 30 driven to the second position. Specifically, the movable pick-up stage 100 and/or the carrier stage 300 may be adjusted based on the alignment offset to perform the alignment compensation operation on the first element 20 and the second element 30 at the second position. Then, the movable pick-up stage 100 and/or the carrier stage 300 may be moved in the height direction to drive the first element 20 and the second element 30 to the bonding position. Or, while moving the movable pick-up stage 100 and/or the carrier stage 300 in the height direction to drive the first element 20 and the second element 30 to the bonding position, the movable pick-up stage 100 and/or the carrier stage 300 may be adjusted based on the alignment offset to perform the alignment compensation operation on the first element 20 and the second element 30.

At block S30: determining an alignment offset between the first element and the second element based on the first relative positional relationship and the second relative positional relationship.

In some embodiments, the operation flow of S30 is as follows.

An angular deviation between the first element and the second element is determined based on the first relative positional relationship and the second relative positional relationship; the relative positions of the first element and the second element are corrected based on the angular deviation; the alignment offset between the first element and the second element is determined based on the corrected relative positions.

To determine the relative relationship between the first element and the second element, the first coordinate system and the second coordinate system need to be merged into a bonding coordinate system.

Specifically, using the first correction mark D1 of the correction component as a reference, the first coordinate system and the second coordinate system may be merged into a bonding coordinate system. That is, the coordinate information D1 (x_{D1}, y_{D1}) of the first correction mark D1 in the first coordinate system is equal to the coordinate information D3 (x_{D3}, y_{D3}) in the second coordinate system. Consequently, the coordinate information of the first alignment mark B1 of the first element 20 and the third alignment mark T1 of the second element 30 in the bonding coordinate system is obtained, such as the coordinate information given earlier. Then, perform a difference calculation based on the coordinate information.

In the case of one correction mark, the coordinate information of the correction mark in the first coordinate system may equal the coordinate information of the correction mark in the second coordinate system. Then, based on the first alignment mark of the first element 20 and the third alignment mark of the second element 30, the coordinate difference between the first element 20 and the second element 30 is determined as the alignment offset.

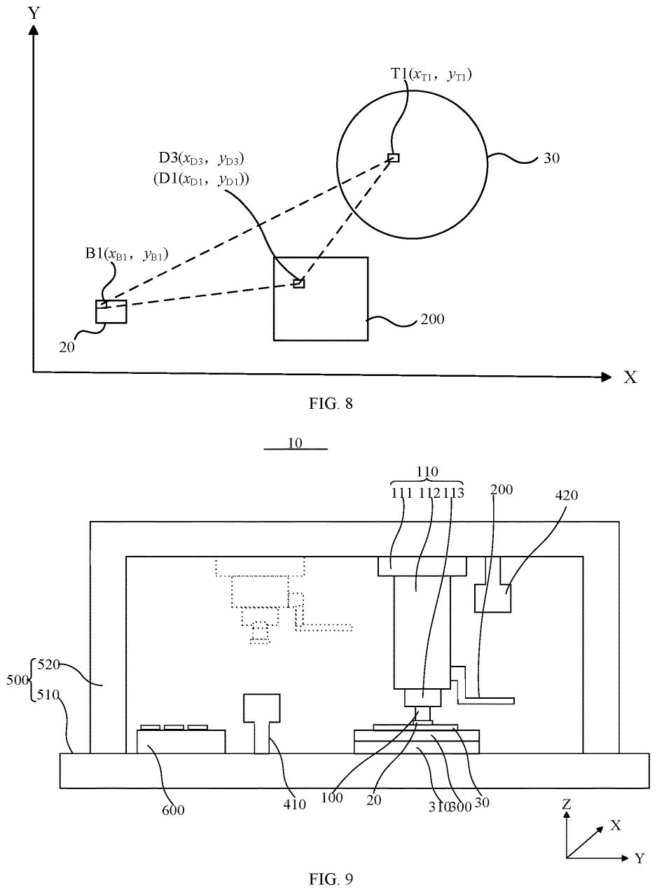

Referring to FIG. 8, FIG. 8 is a schematic diagram of a bonding coordinate system corresponding to a bonding apparatus according to some embodiments of the present disclosure.

As shown in FIG. 8, in the bonding coordinate system, based on the coordinate information (x_{B1}, y_{B1}) of the first alignment mark B1 and the coordinate information (x_{T1}, y_{T1}) of the third alignment mark T1, an X-axis difference and a Y-axis difference between the first element 20 and the second element 30 may be determined. Then, based on the X-axis difference and the Y-axis difference, the alignment offset between the first element and the second element is determined.

At block S40: based on the alignment offset, driving the first element and/or the second element to adjust to perform the alignment compensation operation, for aligning the first element and the second element and bonding the first element and the second element.

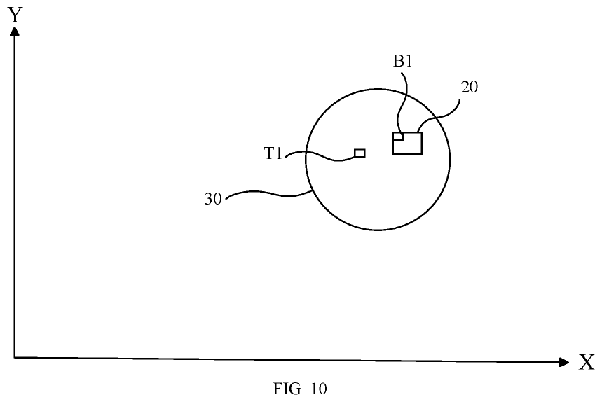

Referring to FIGS. 9 and 10, FIG. 9 is a schematic diagram of a process of bonding a first element and a second element according to some embodiments of the present disclosure, and FIG. 10 is a schematic diagram of coordinate information of a first element and a second element, that are bonded, in a bonding coordinate system according to some embodiments of the present disclosure.

As shown in FIG. 9, after obtaining the alignment offset, the first element and/or the second element may be driven to perform bonding.

In response to determining the alignment offset between the first element 20 and the second element 30, the correction mark of the correction component 200 maintains the first relative positional relationship with the alignment mark of the first element 20. The first element 20 may be driven to the second position. The image-acquisition device is configured to recognize the alignment mark of the second element 30 and the correction mark of the correction component 200, obtain the difference between the alignment mark of the first element 20 and the alignment mark of the second element 30 as the alignment offset, and execute the alignment compensation operation. Or, in response to determining the alignment offset between the first element 20 and the second element 30, the correction mark of the correction component 200 and the alignment mark of the second element 30 indicate the second relative position. The first element 20 may be driven to the second position. The image-acquisition device is configured to recognize the alignment mark of the first element 20 and the correction mark of the correction component 200, obtain the difference between the alignment mark of the first element and the alignment mark of the second element as the alignment offset, and execute the alignment compensation operation.

That is, the correction mark of the correction component 200 may either maintain the first relative positional relationship with the alignment mark of the first element 20, or the correction mark of the correction component 200 may maintain the second relative positional relationship with the alignment mark of the second element 30, which may be set according to actual situations.

In some embodiments, after obtaining the alignment offset, the first driving member 111 and the third driving member 113 may be driven to adjust the first element 20 on the movable pick-up stage 100. Based on the X-axis difference and Y-axis difference, the first drive assembly 110 is driven to perform the alignment compensation operation between the first element 20 and the second element 30, aligning the first element 20 with the second element 30.

In other embodiments, after obtaining the alignment offset, based on the X-axis difference and Y-axis difference, the second drive assembly 310 may be driven to adjust the second element 30 on the carrier stage 300, performing the alignment compensation operation between the first element 20 and the second element 30, aligning the first element 20 with the second element 30. Also, the angular deviation determined based on the first relative positional relationship and the second relative positional relationship may be used to drive the first drive assembly 110 and/or the second drive assembly 310 to adjust the angle of the first element 20 and the second element 30.

In other embodiments, after obtaining the alignment offset, both the first drive assembly 110 and the second drive assembly 310 may be driven simultaneously to adjust the first element 20 and the second element 30, performing the alignment compensation operation between the first element 20 and the second element 30 more quickly, thereby aligning the first element 20 with the second element 30.

After aligning the first element 20 with the second element 30, the first drive assembly 110 may be driven to move the movable pick-up stage 100 carrying the first element 20 in the height direction, such as moving it down, such that the lowered first element 20 contacts the second element 30 and bonds, thereby bonding the bonding position of the first element 20 with the bonding position of the second element 30, as shown in FIG. 10.

In the embodiments, the first relative positional relationship between the first element 20 and the correction component 200 in the first field of view is obtained, and the second relative positional relationship between the second element 30 and the correction component 200 in the second field of view is obtained. The alignment offset between the first element and the second element is determined based on the first relative positional relationship and the second relative positional relationship. Then, based on the alignment offset, the first element and/or the second element are adjusted to align the first element and the second element. That is, the bonding method in the present disclosure may be applied to the aforementioned bonding apparatus, and therefore have the same beneficial effects as the bonding apparatus, which will not be repeated here.

The above are only some embodiments of the present disclosure, and are not intended to limit the scope of the present disclosure. Any equivalent structure or equivalent process transformation made using the description and drawings of the present disclosure, or direct or indirect application to other related technical fields, shall likewise be included within the scope of the present disclosure.

What is claimed is:

1. A bonding apparatus for a chip, comprising:
a movable pick-up stage, configured to move a first element;
a carrier stage, configured to carry and move a second element;
a correction component, configured to provide a correction mark; wherein the correction component maintains a fixed distance from the first element or the second element; and
an image-acquisition device, configured to read an alignment mark of the first element and the correction mark of the correction component, and determine a first relative positional relationship between the first element and the correction component based on the alignment mark of the first element and the correction mark; and further configured to read an alignment mark of the second element and the correction mark of the correction component, and determine a second relative positional relationship between the second element and the correction component based on the alignment mark of the second element and the correction mark;
wherein the bonding apparatus is configured to determine an alignment offset between the first element and the second element based on the first relative positional relationship and the second relative positional relationship; and based on the alignment offset, drive at least one of the movable pick-up stage and the carrier stage to perform adjustments for executing an alignment compensation operation, enabling the first element and the second element to be aligned and bonded.

2. The bonding apparatus according to claim 1, wherein the correction component is disposed on the movable pick-up stage;
wherein, in response to the bonding apparatus executing the alignment compensation operation, the correction component is configured to be driven to a first position or a second position together with the movable pick-up stage; the image-acquisition device is configured to read the alignment mark of the first element at the first position and the correction mark of the correction component to determine the first relative positional relationship, or the image-acquisition device is configured to read the alignment mark of the second element at the second position and the correction mark of the correction component to determine the second relative positional relationship;
wherein the correction component maintains a fixed distance from the first element.

3. The bonding apparatus according to claim 1, wherein the correction component is disposed on the carrier stage;
wherein, in response to the bonding apparatus executing the alignment compensation operation, the correction component is configured to be driven to a first position or a second position together with the carrier stage, enabling the image-acquisition device to read the alignment mark of the first element at the first position and the correction mark of the correction component to determine the first relative positional relationship, or enabling the image-acquisition device to read the alignment mark of the second element at the second position and the correction mark of the correction component to determine the second relative positional relationship;
wherein the correction component maintains a fixed distance from the second element.

4. The bonding apparatus according to claim 1, wherein the image-acquisition device comprises a first field of view and a second field of view;
in response to the bonding apparatus executing the alignment compensation operation, the image-acquisition device is configured to recognize the alignment mark of the first element and the correction mark of the correction component via the first field of view, and is configured to recognize the alignment mark of the second element and the correction mark of the correction component via the second field of view.

5. The bonding apparatus according to claim 4, wherein the second field of view of the image-acquisition device is located in a same direction as the correction component, the first element, and the second element simultaneously;
in response to the bonding apparatus executing the alignment compensation operation, the correction component is configured as a transparent, semi-transparent, or perforated calibration sheet.

6. The bonding apparatus according to claim 5, wherein the correction component is detachably disposed on the movable pick-up stage or the carrier stage.

7. The bonding apparatus according to claim 4, wherein the image-acquisition device comprises a first image-acquisition device and a second image-acquisition device;
in response to the bonding apparatus executing the alignment compensation operation, the movable pick-up stage and the correction component are driven to a first position, and the first image-acquisition device is configured to recognize the alignment mark of the first element and the correction mark of the correction component within the first field of view;
then the movable pick-up stage and the correction component are driven to a second position, and the second image-acquisition device is configured to recognize the alignment mark of the second element and the correction mark of the correction component within the second field of view.

8. The bonding apparatus according to claim 7, wherein the first image-acquisition device comprises at least one first image acquisition unit, and the at least one first image acquisition unit defines the first field of view;
the second image-acquisition device comprises at least one second image acquisition unit, and the at least one second image acquisition unit defines the second field of view.

9. The bonding apparatus according to claim 1, wherein, in response to the alignment offset between the first element and the second element being determined, the correction mark of the correction component maintains the first relative positional relationship with the alignment mark of the first element, and the first element is driven to a second position; the image-acquisition device is configured to recognize the alignment mark of the second element and the correction mark of the correction component, and obtain a difference between the alignment mark of the first element and the alignment mark of the second element as the alignment offset to execute the alignment compensation operation; or
in response to the alignment offset between the first element and the second element being determined, the correction mark of the correction component maintains the second relative positional relationship with the alignment mark of the second element, and the first element is driven to a second position; the image-acquisition device is configured to recognize the alignment mark of the first element and the correction mark of the correction component, and obtain a difference between the alignment mark of the first element and the alignment mark of the second element as the alignment offset to execute the alignment compensation operation.

10. The bonding apparatus according to claim 9, wherein, in response to the bonding apparatus executing a bonding operation, the bonding apparatus adjusts at least one of the movable pick-up stage and the carrier stage based on the alignment offset to perform the alignment compensation operation on the first element and the second element at the second position, and then moves at least one of the movable pick-up stage and the carrier stage in a height direction to drive the first element and the second element to a bonding position; or
in response to the bonding apparatus executing a bonding operation, the bonding apparatus moves at least one of the movable pick-up stage and the carrier stage in a height direction to drive the first element and the second element to a bonding position, and simultaneously adjusts at least one of the movable pick-up stage and the carrier stage based on the alignment offset to perform the alignment compensation operation on the first element and the second element; or
in response to the bonding apparatus executing a bonding operation, the bonding apparatus moves at least one of the movable pick-up stage and the carrier stage in a height direction to drive the first element and the second element to the bonding position, and then, based on the alignment offset, adjusts at least one of the movable pick-up stage and the carrier stage to perform the alignment compensation operation on the first element and the second element.

11. The bonding apparatus according to claim 1, further comprising:
a machine station, comprising a base and a machine frame; wherein the machine frame is disposed on the base, the movable pick-up stage is disposed on the machine frame, and the carrier stage is disposed on the base; at least one of the movable pick-up stage and the carrier stage is movable along an X-direction, a Y-direction, and a height direction Z, and rotatable in a vertical plane perpendicular to a horizontal plane, to adjust a horizontal state of at least one of the movable pick-up stage and the carrier stage.

12. The bonding apparatus according to claim 11, further comprising:
a first drive assembly, disposed on the machine frame and connected to the movable pick-up stage; wherein the first drive assembly is configured to carry the movable pick-up stage to be movable along the X-direction and the Y-direction in the horizontal plane, and the height direction Z, and rotatable in the vertical plane perpendicular to the horizontal plane;
a second drive assembly, disposed on the base and connected to the carrier stage; wherein the second drive assembly is configured to carry the carrier stage to be movable along the X-direction and the Y-direction in the horizontal plane, and the height direction Z, and rotatable in the vertical plane perpendicular to the horizontal plane.

13. A bonding method for a chip, applied to a bonding apparatus and comprising:
acquiring an alignment mark of a first element and a correction mark of a correction component, and determining a first relative positional relationship between the first element and the correction component based on coordinate information of the alignment mark of the first element and coordinate information of the correction mark;
acquiring an alignment mark of a second element and the correction mark of the correction component, and determining a second relative positional relationship between the second element and the correction component based on coordinate information of the alignment mark of the second element and the coordinate information of the correction mark, wherein the correction component maintains a fixed distance with the first element or the second element;
determining an alignment offset between the first element and the second element based on the first relative positional relationship and the second relative positional relationship; and
driving, by the bonding apparatus, at least one of the first element and the second element based on the alignment offset to perform an alignment compensation operation, enabling the first element and the second element to be aligned and bonded.

14. The bonding method according to claim 13, wherein the determining a first relative positional relationship between the first element and the correction component comprises:
in response to the bonding apparatus executing the alignment compensation operation, driving a movable pick-up stage of the bonding apparatus and the correction component to a first position, and recognizing the alignment mark of the first element and the correction mark of the correction component via an image-acquisition device of the bonding apparatus; and
determining the first relative positional relationship based on the coordinate information of the alignment mark of the first element and the coordinate information of the correction mark.

15. The bonding method according to claim 13, wherein a carrier stage of the bonding apparatus is configured to carry and move the second element;
the determining a second relative positional relationship between the second element and the correction component comprises:
in response to the bonding apparatus executing the alignment compensation operation, driving the carrier stage of the bonding apparatus and the correction component to a second position, and recognizing the alignment mark of the second element and the correction mark of the correction component via an image-acquisition device of the bonding apparatus; and
determining the second relative positional relationship based on the coordinate information of the alignment mark of the second element and the coordinate information of the correction mark.

16. The bonding method according to claim 13, wherein, in response to the alignment offset between the first element and the second element being determined, the correction mark of the correction component maintains the first relative positional relationship with the alignment mark of the first element, and the first element is driven to a second position; the image-acquisition device is configured to recognize the alignment mark of the second element and the correction mark of the correction component, and obtain the difference between the alignment mark of the first element and the alignment mark of the second element as the alignment offset to execute the alignment compensation operation; or
in response to the alignment offset between the first element and the second element being determined, the correction mark of the correction component maintains the second relative positional relationship with the alignment mark of the second element, and the first element is driven to a second position; the image-acquisition device is configured to recognize the alignment mark of the first element and the correction mark of the correction component, and obtain a difference between the alignment mark of the first element and the alignment mark of the second element as the alignment offset to execute the alignment compensation operation.

17. The bonding method according to claim 13, wherein, in response to the bonding apparatus executing a bonding operation, the first element is configured as one of a chip to be bonded and a wafer to be bonded, and the second element is configured as the other of the wafer to be bonded and the chip to be bonded;
wherein the driving, by the bonding apparatus, at least one of the first element and the second element based on the alignment offset to perform an alignment compensation operation comprises:
moving the first element and the second element to a second position via at least one of the movable pick-up stage and the carrier stage, for executing the alignment compensation operation to align the first element and the second element driven to the second position.

18. The bonding method according to claim 17, wherein the moving the first element and the second element to a second position via at least one of the movable pick-up stage and the carrier stage, for executing the alignment compensation operation to align the first element and the second element driven to the second position, comprises:
adjusting at least one of the movable pick-up stage and the carrier stage based on the alignment offset to perform the alignment compensation operation on the first element and the second element at the second position, and then moving at least one of the movable pick-up stage and the carrier stage in a height direction to drive the first element and the second element to a bonding position; or
moving at least one of the movable pick-up stage and the carrier stage in a height direction to drive the first element and the second element to the bonding position, and simultaneously adjusting at least one of the movable pick-up stage and the carrier stage based on the alignment offset to perform the alignment compensation operation on the first element and the second element; or
moving at least one of the movable pick-up stage and the carrier stage in a height direction to drive the first element and the second element to the bonding position, and then, based on the alignment offset, adjusting at least one of the movable pick-up stage and the carrier stage to perform the alignment compensation operation on the first element and the second element.

19. The bonding method according to claim 13, wherein the determining an alignment offset between the first element and the second element based on the first relative positional relationship and the second relative positional relationship comprises:
determining an angular deviation between the first element and the second element based on the first relative positional relationship and the second relative positional relationship;
correcting relative positions of the first element and the second element based on the angular deviation; and
determining the alignment offset between the first element and the second element based on the corrected relative positions.

20. A bonding method for a chip, comprising:
providing a correction component, wherein the correction component is a transparent, semi-transparent, or perforated alignment plate arranged with an alignment mark;
configuring the correction component to maintain a fixed distance from a first element or a second element;
driving the correction component and the first element to a first position, and simultaneously reading, by an image-acquisition device, an alignment mark of the first element at the first position and the alignment mark of the correction component through or via the correction component, to determine a first relative positional relationship between the first element and the correction component;
driving the correction component and the second element to a second position, and simultaneously reading, by the image-acquisition device, an alignment mark of the second element at the second position and the alignment mark of the correction component through or via the correction component, to determine a second relative positional relationship between the second element and the correction component;
determining an alignment deviation between the first element and the second element based on the first relative positional relationship and the second relative positional relationship; and
adjusting the first element and/or the second element based on the alignment deviation to align and bond the first element and the second element.
